(19) United States
(12) Patent Application Publication
(10) Pub. No.: US 2025/0096582 A1
(43) Pub. Date: Mar. 20, 2025

(54) CIRCUITRY CONNECTING TO BATTERY, REGULATION CIRCUIT AND METHOD THEREOF

(71) Applicant: INNOSCIENCE (ZHUHAI) TECHNOLOGY CO., LTD., Guangdong (CN)

(72) Inventors: Meihui LI, Guangdong (CN); Jiajie CUI, Guangdong (CN); Huaifeng WANG, Guangdong (CN)

(73) Assignee: INNOSCIENCE (ZHUHAI) TECHNOLOGY CO., LTD., Guangdong (CN)

(21) Appl. No.: 18/566,671

(22) PCT Filed: Aug. 8, 2022
(86) PCT No.: PCT/CN2022/110761

§ 371 Date: Dec. 4, 2023

(51) Int. Cl. H02J 7/00; H10D 80/20

(52) U.S. Cl. CPC H02J 7/00302; H02J 7/00306; H02J 7/007182; H10D 80/251

(57) ABSTRACT

The present disclosure provides a circuitry electrically connected to a battery, a regulation circuit and an operating method thereof. The circuitry includes a regulation circuit, a first transistor set and a second transistor set. The regulation circuit includes a first node, a second node and a third node. The first node electrically connects to a power source, and the second node electrically connects to a cathode of the battery. When the circuitry is operated in a first mode, the first node electrically connects to the third node through the first transistor set to create a first path from the first node to the second node. When the circuitry is operated in a second mode, the second node electrically connects to the third node through the second transistor set to create a second path from the second node to the first node.

### BACKGROUND

### 1. Technical Field

The present disclosure relates to a circuitry, a regulation circuit and an operating method thereof, and more particularly to a circuitry and a regulation circuit for protecting a battery.

### 2. Description of the Related Art

Components including direct bandgap semiconductors, for example, semiconductor components including group III-V materials or group III-V compounds (Category: III-V compounds) can operate or work under a variety of conditions or in a variety of environments (e.g., at different voltages and frequencies) due to their characteristics.

The semiconductor components may include a heterojunction bipolar transistor (HBT), a heterojunction field effect transistor (HFET), a high-electron-mobility transistor (HEMT), a modulation-doped FET (MODFET) and the like.

### SUMMARY

In some embodiments of the present disclosure, a circuitry electrically connected to a battery is provided. The circuitry includes a regulation circuit, a first set of transistors and a second set of transistors. The regulation circuit includes a first node, a second node and a third node. The first node electrically connects to a power source, and the second node electrically connects to a cathode of the battery. The first set of transistors are electrically connecting to the first node and the third node of the regulation circuit. The second set of transistors are electrically connecting to the second node and the third node of the regulation circuit. When the circuitry is operated in a first mode, the first node electrically connects to the third node through the first set of transistors to create a first path from the first node to the second node. When the circuitry is operated in a second mode, the second node electrically connects to the third node through the second set of transistors to create a second path from the second node to the first node.

In some embodiments of the present disclosure, a regulation circuit is provided. The regulation circuit includes a first transistor, a second transistor and a third transistor A drain electrode of the first transistor connects to a first node coupling to a power source, and a source electrode of the first transistor connects to a second node coupling to a battery. A gate electrode of the second transistor connects to a gate electrode of the first transistor, and a source electrode of the second transistor connects to the second node. A gate electrode of the third transistor connects to the gate electrode of the first transistor, and a source electrode of the third transistor connects to the first node. The regulation circuit is configured to allow carrying a first path during a first mode and carrying a second path during a second mode.

In some embodiments of the present disclosure, a method for operating a circuitry is provided. The method includes providing a regulation circuit comprising a first node, a second node and a third node, wherein the first node electrically connects to a power source, and the second node electrically connects to a cathode of a battery; providing a first set of transistors, electrically connecting to the first node and the third node of the regulation circuit; and providing a second set of transistors, electrically connecting to the second node and the third node of the regulation circuit. When the circuitry is operated in a first mode, the regulation circuit is turned off and a first path is provided from the first node to the second node by electrically connecting the third node to the first node through the first set of transistors. When the circuitry is operated in a second mode, the regulation circuit is turned off and a second path is provided from the second node to the first node by electrically connecting the third node to the second node through the second set of transistors.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may have arbitrarily increased or reduced for clarity of discussion.

FIG. 1 is a schematic circuit diagram of a regulation circuit according to some embodiments of the present disclosure.

FIG. 2A is a top view of a layout of a regulation circuit according to some embodiments of the present disclosure.

FIG. 2B is a cross-sectional view of a regulation circuit according to some embodiments of the present disclosure.

FIG. 2C is another cross-sectional view of a regulation circuit according to some embodiments of the present disclosure.

FIG. 3A is a schematic circuit diagram of a circuitry according to some embodiments of the present disclosure.

FIG. 3B is a schematic circuit diagram of a transistor and a logic gate to some embodiments of the present disclosure.

FIG. 4A is a schematic circuit diagram of a circuitry according to some embodiments of the present disclosure.

FIG. 4B is another schematic circuit diagram of a circuitry according to some embodiments of the present disclosure.

FIG. 4C are schematics illustrating the voltages on different nodes according to some embodiments of the present disclosure.

FIG. 5A is a schematic circuit diagram of a circuitry according to some embodiments of the present disclosure.

FIG. 5B is another schematic circuit diagram of a circuitry according to some embodiments of the present disclosure.

FIG. 5C are schematics illustrating the voltages on different nodes according to some embodiments of the present disclosure.

FIG. 6A, FIG. 6B, and FIG. 6C are a flowchart of operations in the manufacture of a circuitry according to some embodiments of the present disclosure.

FIG. 7 is a flowchart of operations in the manufacture of a circuitry according to some embodiments of the present disclosure.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may have formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

A direct band gap material, such as a group III-V compound, may include but is not limited to, for example, gallium arsenide (GaAs), indium phosphide (InP), gallium nitride (GaN), Indium gallium arsenide (InGaAs), Indium aluminum arsenide (InAlAs), and the like.

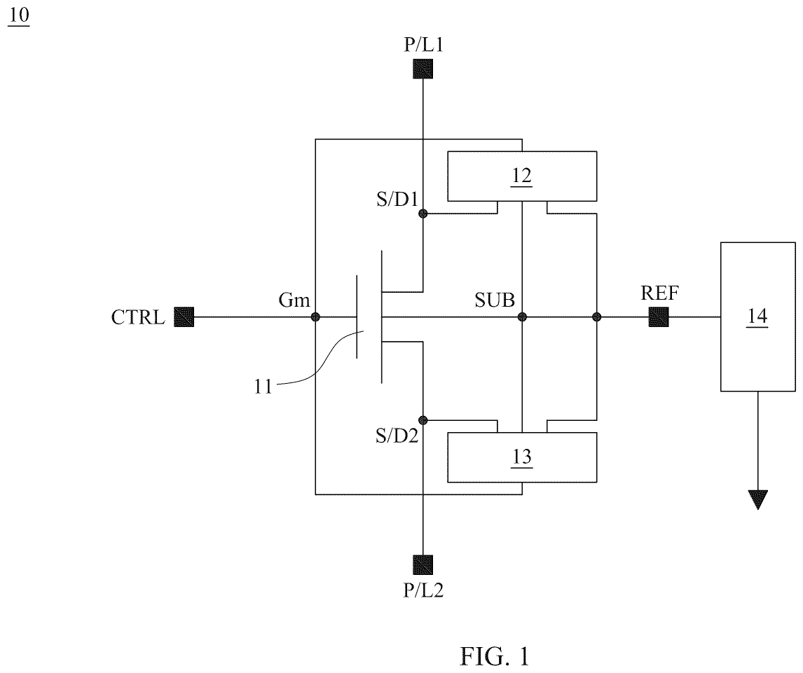

FIG. 1 is a schematic circuit diagram of a regulation circuit 10 according to some embodiments of the present disclosure. As shown in FIG. 1, the regulation circuit 10 has a control node CTRL, a power/load node P/L1, a power/load node P/2, a reference node REF and a substrate. In some embodiments, the regulation circuit 10 includes a transistor 11 and a substrate potential management circuit configured to manage the voltage of the substrate of the regulation circuit 10.

The transistor 11 can be a substrate-coupled transistor. The transistor 11 may have a gate terminal Gm electrically connected to the control node CTRL, a source/drain terminal S/D1 electrically connected to the power/load node P/L1, a source/drain terminal S/D2 electrically connected to the power/load node P/L2, and a gate terminal Gm electrically connected to the substrate terminal SUB of the substrate.

The source/drain terminal S/D1 and the source/drain terminal S/D2 may function as a source or a drain depending on the direction of current flowing therebetween. For example, when current flows from S/D1 to S/D2, the terminal S/D1 acts as a source and the source/drain terminal S/D2 acts as a drain of transistor 11. In addition, when the current flows from the source/drain terminals S/D2 to S/D1, the source/drain terminal S/D1 functions as a drain, and S/D2 functions as a source of the transistor 11.

The regulation circuit 10 is operable in a direction during an operation mode in which the power/load node P/L1 is biased at a voltage higher than the voltage applied to the power/load node P/L2. The transistor 11 can be switched to ON and produce a current flowing in the direction from the source/drain terminal S/D1 to the source/drain terminal S/D2.

For example, the power/load node P/L1 of the regulation circuit 10 may be connected to a power supply, and the power/load may be connected to the load. Alternatively, the regulation circuit 10 may operate in the direction in the mode of operation. The transistor 11 can be switched to ON and produce a current flowing in the direction from the source/drain terminal to the source/drain terminal. For example, the power/load node P/L1 of the regulation circuit 10 may be connected to the load, and the power/load may be connected to the power supply.

The substrate potential management circuit may include a potential stabilization element 12 having a control terminal electrically connected to the control node, a conductive terminal electrically connected to the substrate, and the substrate terminal electrically connected to the substrate. The potential stabilization element 12 can be a transistor.

The substrate potential management circuit may further comprise a potential stabilization element 13 having a control terminal electrically connected to the control node, a conductive terminal electrically connected to the power/load node P/L2, a conductive terminal electrically connected to the substrate, and the substrate terminal electrically connected to the substrate. The potential stabilization element 13 can be a transistor.

The substrate may be electrically connected to the potential stabilizing element 14 through the reference node. When a high-level voltage is applied to the control node, the potential stabilization element 12 may have a resistor with resistance lower than the resistor of the potential stabilization element 14, and the potential stabilization element 13 may have a resistor with lower resistance than the resistor. Therefore, the potential of the substrate is substantially equal to the lower one of the potentials of the power/load node P/L1 and P/L2. The potential stabilization element 14 can be a transistor.

When a low-level voltage is applied to the control node, the resistance of the resistor may higher than that of the resistance, and the resistance of the resistor may higher than that of the resistance, so that the potential of the substrate is substantially equal to the ground potential.

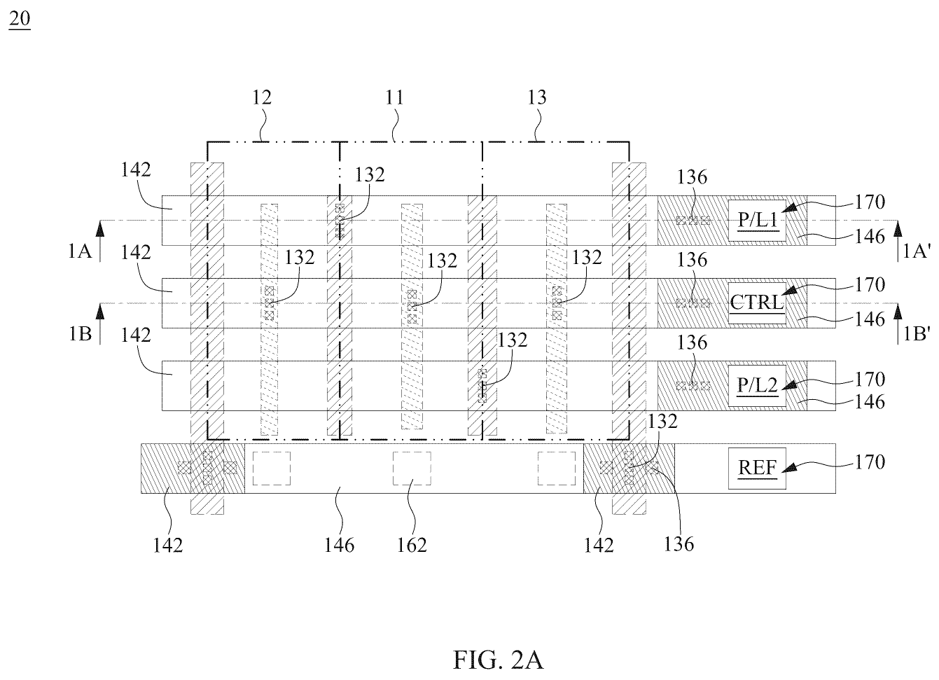

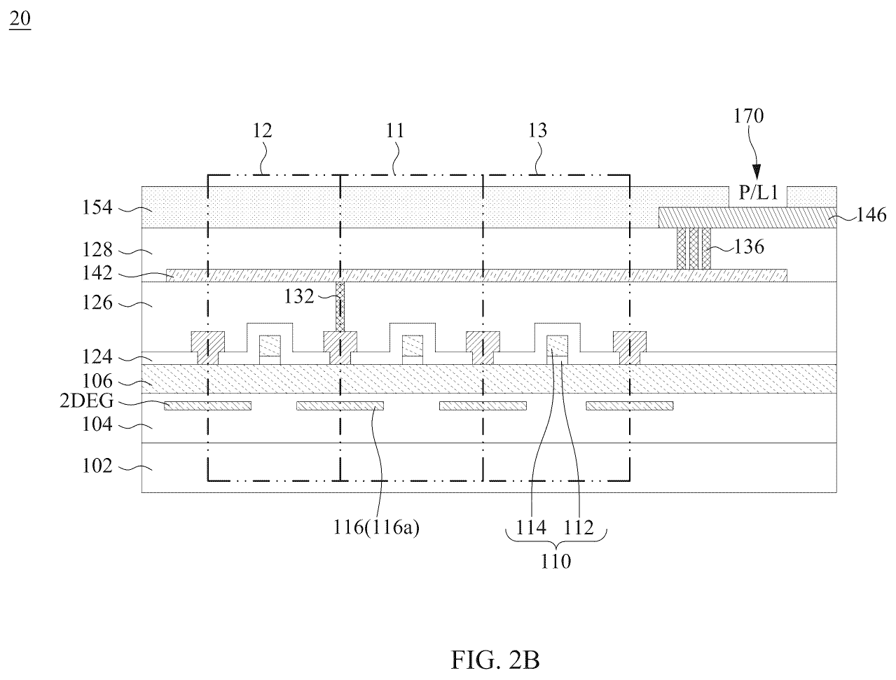

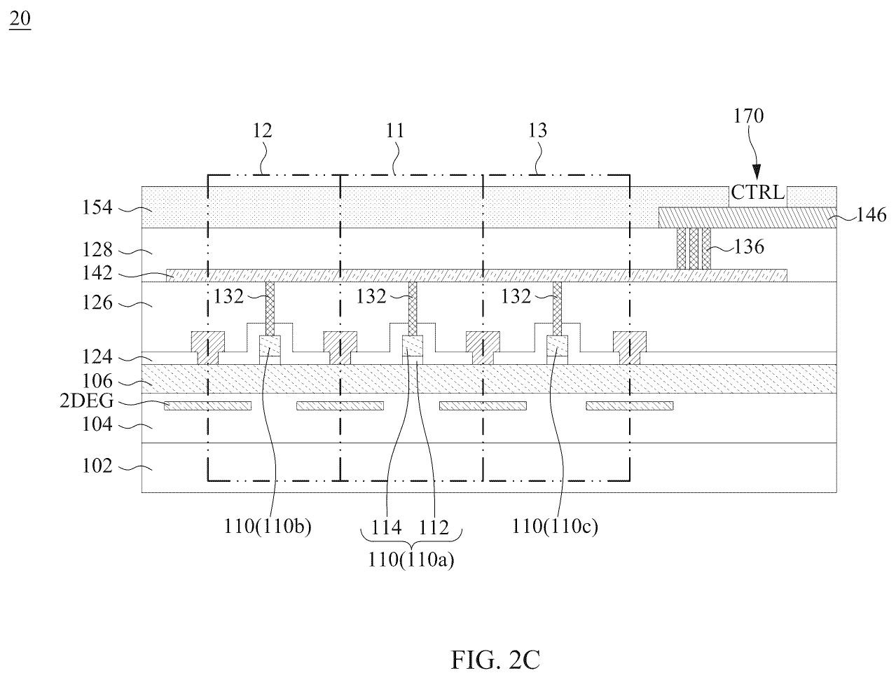

FIG. 2A is a top view of a layout of a regulation circuit 20 according to some embodiments of the present disclosure. FIG. 2B is a cross-sectional view of the regulation circuit 20 according to some embodiments of the present disclosure. FIG. 2C is another cross-sectional view of the regulation circuit 20 according to some embodiments of the present disclosure. According to FIG. 2A, FIG. 2B, and FIG. 2C, the regulation circuit 20 may include a substrate 102, a nitride-based semiconductor layer 104, a nitride-based semiconductor layer 106, a gate electrode 110, an S/D electrode 116, a passivation layer 124, a passivation layer 126, a passivation layer 128, one or more conductive vias 132, one or more conductive vias 136, one or more conductive lines 142, one or more conductive vias lines 146, a protective layer 154 and one or more gallium vias (TGVs) 162 and conductive pads 170.

The substrate 102 may include, for example, but is not limited to, silicon (Si), doped silicon (doped Si), silicon carbide (SiC), germanium silicide (SiGe), gallium arsenide (GaAs), or another semiconductor material. In some embodiments, the substrate 102 may include an intrinsic semiconductor material. In some embodiments, the substrate 102 may include a p-type semiconductor material. In some embodiments, the substrate 102 may include a silicon layer doped with boron (B). In some embodiments, the substrate 102 may include a silicon layer doped with gallium (Ga). In some embodiments, the substrate 102 may include an n-type semiconductor material.

The nitride semiconductor layer 104 may be disposed on the substrate 102. The nitride semiconductor layer 104 may be disposed on the buffer layer. The nitride semiconductor layer 104 may include, for example, but is not limited to, group III nitride. The nitride semiconductor layer 104 may include, for example, but is not limited to, GaN. The nitride semiconductor layer 104 may include, for example, but is not limited to, AlN. The nitride semiconductor layer 104 may include, for example, but is not limited to, InN. The nitride semiconductor layer 104 may include, for example, but is not limited to, compound InₓAl_{y}Ga_{1-x-y}N, where x+y≤1. The nitride semiconductor layer 104 may include, for example, but is not limited to, compound Al_{y}Ga_{(1-y)}N, where y≤1.

The nitride semiconductor layer 106 may be disposed on the nitride semiconductor layer 104. The nitride semiconductor layer 106 may include, for example, but is not limited to, group III nitride. The nitride semiconductor layer 106 may include, for example, but is not limited to, compound Al_{y}Ga_{(1-y)}N, where y≤1. The nitride semiconductor layer 106 may include, for example, but is not limited to, GaN. The nitride semiconductor layer 106 may include, for example, but is not limited to, AlN. The nitride semiconductor layer 106 may include, for example, but is not limited to, InN. The nitride semiconductor layer 106 may include, for example, but is not limited to, compound InₓAl_{y}Ga_{1-x-y}N, where x+y≤1.

A heterojunction may be formed between the nitride semiconductor layer 106 and the nitride semiconductor layer 104. The nitride semiconductor layer 106 may have a band gap greater than a band gap of the nitride semiconductor layer 104. For example, the nitride semiconductor layer 106 may include AlGaN that may have a band gap of about 4 eV, and the nitride semiconductor layer 104 may include GaN that may have a band gap of about 3.4 eV.

The nitride semiconductor layer 104 may be used as a channel layer. In the regulation circuit 20, the nitride semiconductor layer 104 may be used as a channel layer disposed on the semiconductor substrate 102. The nitride semiconductor layer 106 may be used as a barrier layer. The nitride semiconductor layer 106 may be used as a barrier layer disposed on the nitride semiconductor layer 104.

Because the band gap of the nitride semiconductor layer 104 is less than the band gap of the nitride semiconductor layer 106, two dimensional electron gas (2DEG) may be formed in the nitride semiconductor layer 104. Because the band gap of the nitride semiconductor layer 104 is less than the band gap of the nitride semiconductor layer 106, the 2DEG may be formed in the nitride semiconductor layer 104 and the 2DEG is close to the interface of the nitride semiconductor layer 106 and the nitride semiconductor layer 104.

Because the band gap of the nitride semiconductor layer 106 is greater than the band gap of the nitride semiconductor layer 104, 2DEG may be formed in the nitride semiconductor layer 104. Because the band gap of the nitride semiconductor layer 106 is greater than the band gap of the nitride semiconductor layer 104, 2DEG may be formed in the nitride semiconductor layer 104 and the 2DEG is close to the interface of the nitride semiconductor layer 106 and the nitride semiconductor layer 104.

The gate electrode 110 is disposed on or over the nitride semiconductor layer 106. Each of the gate electrodes 110 may include one of the gate semiconductor layer 112 and a gate metal layer 114. The gate semiconductor layer 112 and the gate metal layer 114 are stacked on the nitride semiconductor layer 106. The gate semiconductor layer 112 is between the nitride semiconductor layer 106 and the gate metal layer 114. The gate semiconductor layer 112 and the gate metal layer 144 may form a Schottky barrier.

The transistor 11, the transistor 12, and the transistor 13 may be operated on an enhancement mode which are normally off when their gate electrode 110 is at approximately zero bias. Specifically, the gate semiconductor layer 112 may be a p-type doped III-V compound semiconductor layer.

Exemplary materials for the p-doped III-V compound semiconductor layer 112 may include, for example, but not limited to, p-doped III-V nitride semiconductor materials such as p-type GaN, p-type AlGaN, p-type InN, p-type AlInN, p-type InGaN, p-type AlInGaN, or a combination thereof.

In some embodiments, the nitride semiconductor layer 104 includes undopped GaN, and the nitride semiconductor layer 106 includes AlGaN, and p-type doped III-V compound semiconductor layer 112 is a p-type GaN layer. The p-type GaN layer can bend the underlying band structure upward and deplete the corresponding region of the 2DEG region, thereby placing the regulation circuit 10 20 in an off-state condition.

In some embodiments, the gate electrode 110 may include a metal or a metal compound. The gate electrode 110 may be formed as a single layer, or multiple layers having the same or different compositions. Exemplary materials for metals or metal compounds may include, for example, but not limited to, W, Au, Pd, Ti, Ta, Co, Ni, Pt, Mo, TiN, TaN, Si, metal alloys or compounds thereof, or other metal compounds.

The S/D electrode 116 is disposed on the nitride semiconductor layer 106. The S/D electrodes 116 may be located at opposite sides of the corresponding gate electrode 110, although other configurations may be used, especially when multiple source, drain, or gate electrodes are employed in the device.

In some embodiments, the distance between the gate electrode and the drain electrode equals to a distance between the gate electrode and the source electrode. In some embodiments, adjacent S/D electrodes 116 are symmetrical with respect to gate electrode 110 therebetween. In some embodiments, adjacent S/D electrodes 116 may optionally be asymmetrical with respect to gate electrodes 110 therebetween. That is, one of the S/D electrodes 116 may be closer to the gate electrode 110 than the other of the S/D electrodes 116.

In some embodiments, the S/D electrodes 116 may include, for example, but not limited to, metals, alloys, doped semiconductor materials (eg, doped crystalline silicon), compounds such as silicides and nitrides, other conductive materials, or combinations thereof. Exemplary materials for the S/D electrode 116 may include, for example, but not limited to, Ti, AlSi, TiN, or combinations thereof.

A passivation layer 124 is disposed over the nitride semiconductor layer 106. The passivation layer 124 may be formed for protection purposes or to enhance the electrical properties of the device. The passivation layer 124 covers the top surface of the nitride semiconductor layer 106. The passivation layer 124 may cover at least two opposite sidewalls of the gate electrode 110. Exemplary materials for passivation layer 124 may include, for example, but not limited to, SiNx, SiOx, Si3N4, SION, SIC, SiBN, SiCBN, oxides, nitrides, poly(2-ethyl-2-oxazoline) (PEOX) or a combination thereof.

The passivation layer 126 is disposed over passivation layer 124 and S/D electrode 116. The passivation layer 126 covers the passivation layer 124 and the S/D electrode 116. Passivation layer 126 may act as a planarization layer having a horizontal top surface to support other layers/elements. Exemplary materials for passivation layer 126 may include, for example, but not limited to, SiNx, SiOx, Si₃N₄, SiON, SiC, SiBN, SiCBN, oxide, PEOX, or combinations thereof.

The conductive vias 132 are disposed within passivation layer 126 and passivation layer 124. Conductive vias 132 penetrate the passivation layer 126 and the passivation layer 124. Conductive vias 132 extend longitudinally to electrically couple with gate electrodes 110 and S/D electrodes 116, respectively. Exemplary materials for conductive vias 132 may include, for example, but not limited to, conductive materials such as metals or alloys.

The conductive lines 142 are disposed on passivation layer 126 and conductive vias 132. The conductive lines 142 are in contact with the conductive vias 132. Conductive lines 142 may be formed by patterning a conductive layer disposed over passivation layer 126 and conductive vias 132. The conductive lines 142 may comprise a single film or multiple films of Ag, Al, Cu, Mo, Ni, alloys thereof, oxides thereof, nitrides thereof, or combinations thereof.

The passivation layer 128 is disposed over passivation layer 126 and conductive traces 142. Passivation layer 128 covers passivation layer 126 and conductive traces 142. Passivation layer 128 may act as a planarization layer having a horizontal top surface to support other layers/elements. Exemplary materials for passivation layer 128 may include, for example, but not limited to, SiNx, SiOx, Si₃N₄, SION, SiC, SiBN, SICBN, oxide, PEOX, or combinations thereof.

The conductive vias 136 are disposed within passivation layer 128. The conductive vias 136 penetrate the passivation layer 128. Conductive vias 136 extend longitudinally to electrically couple with conductive traces 142. The upper surfaces of the conductive vias 136 are not covered by the passivation layer 136. Exemplary materials for conductive vias 136 may include, for example, but not limited to, conductive materials such as metals or alloys.

The conductive lines 146 are disposed on passivation layer 128 and conductive vias 136. The conductive lines 146 are in contact with the conductive vias 136. Exemplary materials for conductive lines 146 may include, for example and without limitation, conductive materials. The conductive lines 146 may comprise a single film or multiple films of Ag, Al, Cu, Mo, Ni, alloys thereof, oxides thereof, nitrides thereof, or combinations thereof.

The TGV 162 is formed to extend longitudinally from the conductive layer 146 and penetrate into the substrate 102. The upper surface of the TGV 162 is not covered by the passivation layer 128. In some embodiments, the TGV 162 may be formed to extend longitudinally from the conductive layer 142 and penetrate into the substrate 102. Exemplary materials for the TGV 162 may include, for example, but not limited to, conductive materials such as metals or alloys.

The protective layer 154 is disposed over passivation layer 128 and conductive layer 146. The protective layer 154 covers the passivation layer 128 and the conductive layer 146. The protective layer 154 can prevent the conductive layer 146 from oxidizing. Portions of conductive layer 146 may be exposed through openings in protective layer 154 to form conductive pads 170.

The conductive pads 170 may include: a control pad CTRL configured to act as a control node; a power/load pad P/L1 configured to act as a power/load node P/L1; and a power/load pad P/L2 configured to act as a control node to act as a power/load node P/L2; and a reference pad REF configured to act as a reference node.

FIG. 2B is a cross-sectional view of a regulation circuit 20 according to some embodiments of the present disclosure. The S/D electrodes 116 may include at least one S/D electrode 116a that is electrically connected to a power/load pad and configured to serve as a source/drain terminal of the transistor 11 and the drain terminal of the transistor 12.

The S/D electrode 116a may be connected to the power/load pad through at least one conductive via 132, at least one conductive trace 142, at least one conductive via 136, and at least one conductive trace 146. In this exemplary structure, the same S/D electrode is shared by the transistor 11 and the transistor 12, so that the chip size can be minimized.

FIG. 2C is another cross-sectional view of a regulation circuit 20 according to some embodiments of the present disclosure. The gate electrode 110 may include at least one gate electrode 110a electrically connected to the control pad and configured to serve as the gate terminal of the transistor 11. The gate electrode 110a may be connected to the control pad through at least one conductive via 132, at least one conductive trace 142, at least one conductive via 136, and at least one conductive trace 146. The gate electrode 110 may further include at least one gate electrode 110b electrically connected to the control pad and configured to serve as the gate terminal of the transistor 12. The gate electrode 110b may be connected to the control pad through at least one conductive via 132, at least one conductive trace 142, at least one conductive via 136, and at least one conductive trace 146.

The gate electrode 110 may further include at least one gate electrode 110c electrically connected to the control pad and configured to serve as the gate terminal of the transistor 13. The gate electrode 110c may be connected to the control pad through at least one conductive via 132, at least one conductive trace 142, at least one conductive via 136, and at least one conductive trace 146.

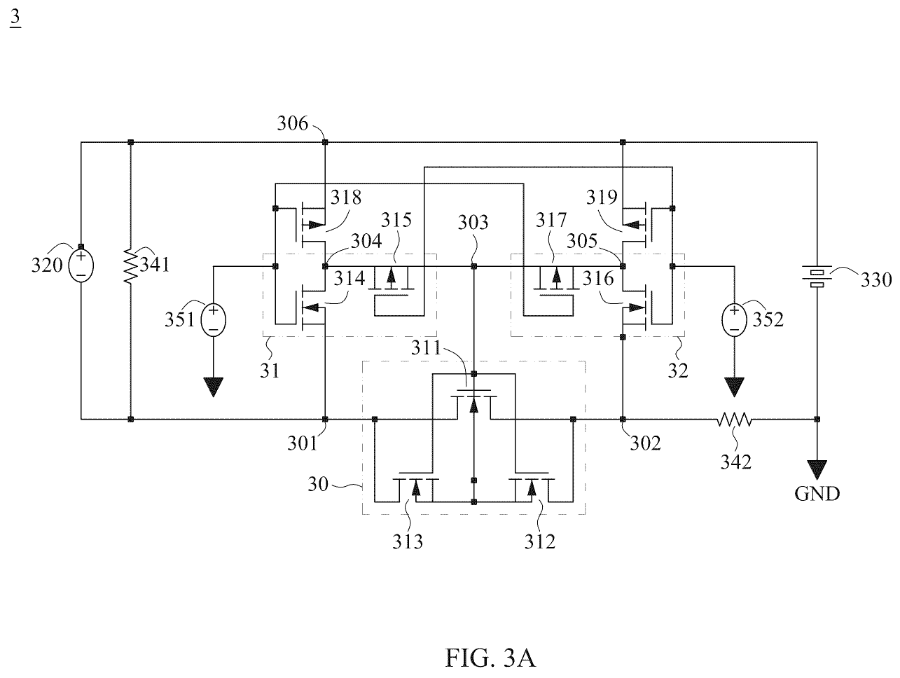

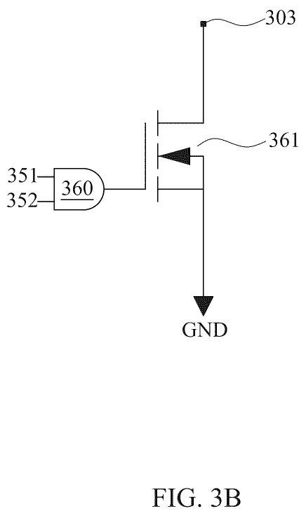

FIG. 3A is a schematic circuit diagram of a circuitry 3 according to some embodiments of the present disclosure. The circuitry 3 can be provided or formed between a power source 320 and a battery 330. The circuitry 3 can electrically connect to the power source 320 and the battery 330. The circuitry 3 can be used to adjust, regulate or control charging and discharging between the power source 320 and the battery 330. The circuitry 3 can be used to protect or prevent the battery 330 from being damaged or degenerated during the charging process or the discharging process.

As shown in FIG. 3A, the circuitry 3 may include a regulation circuit 30, a transistor set 31 and another transistor set 32. In some embodiments, the circuitry 3 may include a regulation circuit 30, a transistor set 31, a transistor set 32, two transistors 318 and 319, two resistors 341 and 342, a control terminal 351 and a control terminal 352. The resistor 341 can be a load of the power source 320.

In some embodiments, the regulation circuit 30 can be arranged between the node 301 and the node 302. The regulation circuit 30 can be coupled between the nodes 301, 302 and 303. The transistor set 31 may be formed between the node 303 and the control terminal 351. The transistor set 32 may be formed between the node 303 and the control terminal 352.

The control terminal 351 can include a voltage source. The control terminal 351 can be biased or receive a voltage of certain logic level. The control terminal 352 can include a voltage source. The control terminal 352 can be biased or receive a voltage of certain logic level. Therefore, by applying different logic levels on the control terminals 351 and 352, the circuitry 3 can be operated in various mode accordingly, such as a normal mode, a charge protection mode, a discharge protection mode and a stand-by mode.

In some embodiments, the regulation circuit 30 can include three transistors 311, 312 and 313. In some embodiments, the regulation circuit 30 can correspond to the regulation circuit 10 of FIG. 1 or the regulation circuit 20 of FIG. 2A to FIG. 2C. More specifically, the transistor 311 may correspond to the transistor 11. The transistor 312 may correspond to the transistor 12. The transistor 313 may correspond to the transistor 13.

As shown in FIG. 3A, the transistor 311 includes a drain electrode connected to first node 301. The transistor 311 includes a source electrode connected to the node 302. The transistor 312 includes a gate electrode connected to a gate electrode of the transistor 311. The transistor 312 includes a source electrode connected to the node 302. The transistor 313 includes a gate electrode connected to the gate electrode of the transistor 311. The transistor 313 includes a source electrode connected to the node 301. The transistor 313 includes a drain electrode connected to a drain electrode of transistor 312. It should be noted that the source/drain electrode may refer to a source or a drain, individually or collectively dependent upon the context.

In some embodiments, the transistor set 31 may include two transistors 314 and 315. The transistor 314 includes a gate electrode connected to the control terminal 351. The transistor 314 includes a source electrode connected to the node 301. The transistor 314 includes a drain electrode connected to a node 304. The transistor 315 includes a gate electrode connected to the control terminal 352. The transistor 315 includes a source electrode connected to the node 303. The transistor 315 includes a drain electrode connected to the node 304.

In some embodiments, the transistor set 32 may include two transistors 316 and 317. The transistor 316 includes a gate electrode connected to the control terminal 352. The transistor 316 includes a source electrode connected to the node 302. The transistor 316 includes a drain electrode connected to a node 305. The transistor 317 includes a gate electrode connected to the control terminal 351. The transistor 317 includes a source electrode connected to the node 305. The transistor 317 includes a drain electrode connected to the node 303.

In some embodiments, the transistor 318 can be electrically connected to the transistor set 31. The transistor 318 can be electrically in series with the transistor 314 of the transistor set 31. In some embodiments, the transistor 318 includes a gate electrode connected to the control terminal 351. The transistor 318 includes a source electrode connected to the node 304. The transistor 318 includes a source electrode connected to a node 306. The node 306 may be electrically connected to the power source 320, the resistor 341 and the anode of the battery 330.

In some embodiments, the transistor 319 can be electrically connected to the transistor set 32. The transistor 319 can be electrically in series with the transistor 316 of the transistor set 32. In some embodiments, the transistor 319 includes a gate electrode connected to the control terminal 352. The transistor 319 includes a source electrode connected to the node 305. The transistor 319 includes a drain electrode connected to the node 306.

In addition, the resistor 342 can be arranged between the node 302 and the ground GND. Furthermore, the cathode of the battery 330 can be electrically connected to the ground GND. The control terminal 351 can be connected between the ground GND and the gate electrodes of the transistors 314 and 318. The control terminal 352 can be connected between the ground GND and the gate electrodes of the transistors 316 and 319.

FIG. 3B is a schematic circuit diagram of a transistor 361 and a logic gate according to some embodiments of the present disclosure. In some embodiments, the logic gate can be an AND gate 360.

As shown in FIG. 3B, a gate electrode of the transistor 361 connects to an output of the AND gate 360. The drain electrode of the transistor 361 connects to the node 303. A source electrode of the transistor 361 connects to the ground GND. In some embodiments, an input of the AND gate 360 connects to the control terminal 351 and the control terminal 352.

In some embodiments, the transistors 314, 316 and 361 can be NMOS transistors. In some embodiments, the transistors 315, 317, 318 and 319 can be PMOS transistors. It should be noted that the transistors 314 to 319 are mainly used for illustration rather than limitation. In some embodiments, the transistors 314 to 319, for example the transistors 315 and 317, can be implemented or replaced by any type of electrical components such as a switch or a diode.

In some embodiments, when the control terminal 351 is at low voltage level and the control terminal 352 is at low voltage level, the circuitry can be operated in a normal mode. During the normal mode, the battery 330 can be charged from the power source 320 or discharged to the power source 320.

In some embodiments, when the control terminal 351 is at low voltage level and the control terminal 352 is at high voltage level, the circuitry can be operated in a discharge protection mode. During the discharge protection mode, the battery 330 can be discharged while a current path can be created from the node 302 to the node 301.

In some embodiments, when the control terminal 351 is at high voltage level and the control terminal 352 is at low voltage level, the circuitry can be operated in a charge protection mode. During the charge protection mode, the battery 330 can be charged while a current path can be created from the node 301 to the node 302.

In some embodiments, when the control terminal 351 is at high voltage level and the control terminal 352 is at high voltage level, the circuitry can be operated in a stand-by mode. During the stand-by mode, battery 330 is not charged or discharged.

During the stand-by mode, the transistors 314 and 316 are turned on, and the transistors 315, 317, 318 and 319 are turned off. Furthermore, the output of the AND gate 360 is high voltage level. The transistor 361 is turned on, and the gate electrode of the regulation circuit 30 is at low voltage level so that the regulation circuit 30 is turned off. As a result, the circuitry 30 enters the stand-by mode.

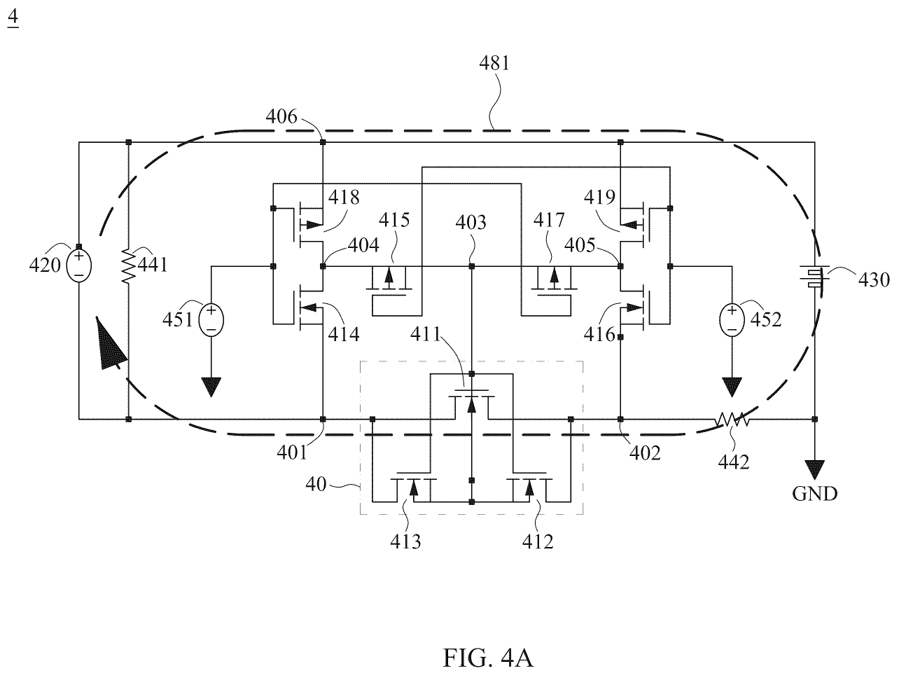

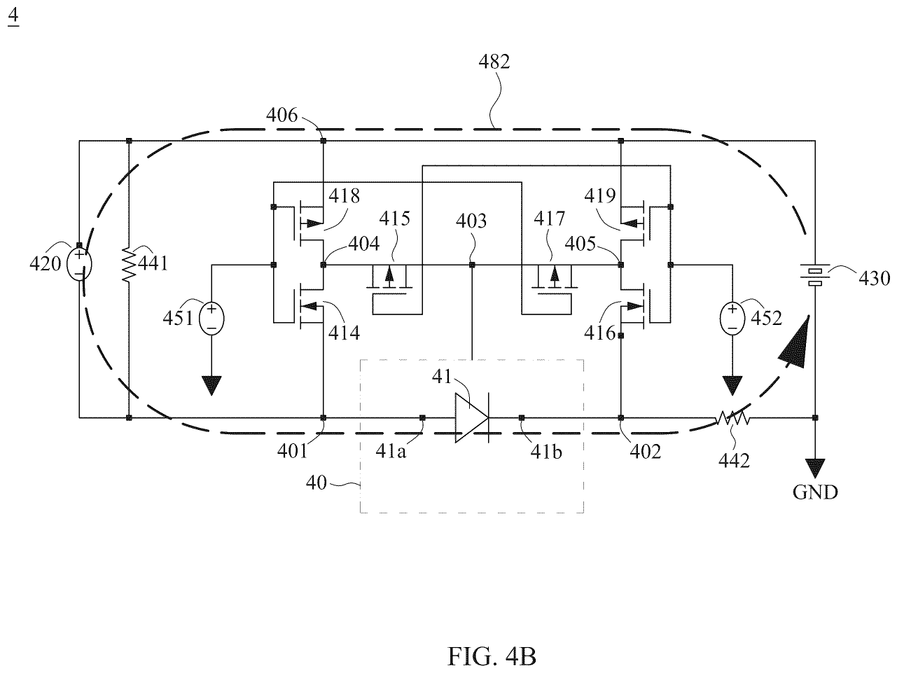

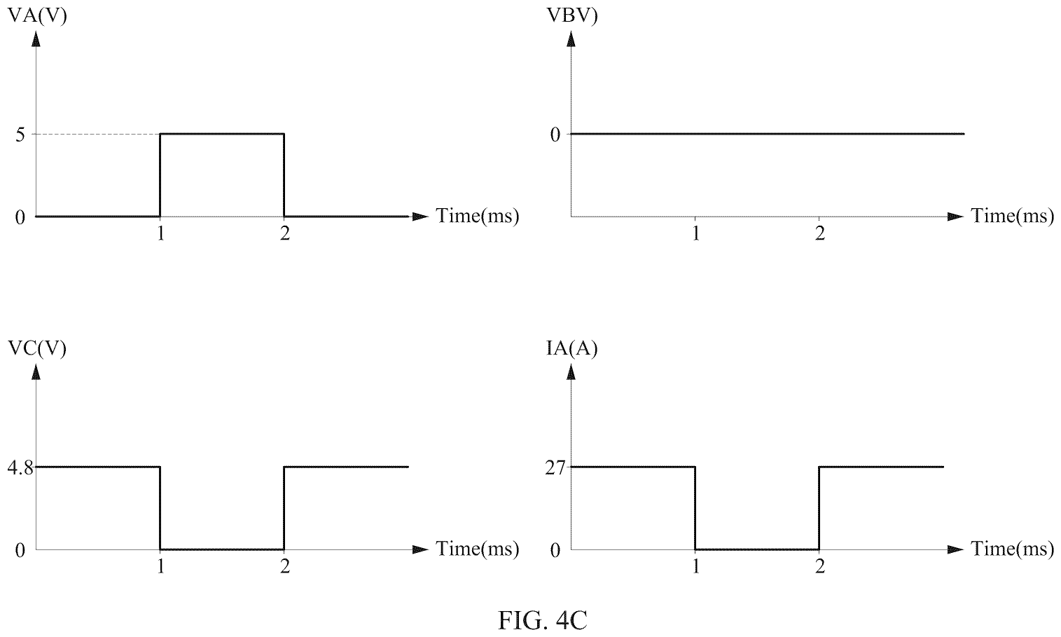

FIG. 4A is a schematic circuit diagram of a circuitry 4 during the charge protection mode according to some embodiments of the present disclosure. In some embodiments, the circuitry 4 can correspond to the circuitry 3 of FIG. 3A.

In some embodiments, during the charge protection mode, the control terminal 451 is at high voltage level and the control terminal 452 is at low voltage level. The transistors 414, 415 and 419 are turned on. The transistors 416, 417 and 418 are turned off. The gate electrode of the transistor 411 is pulled down and becomes low voltage level. Therefore, the regulation circuit 40 can be turned off.

As shown in FIG. 4A, the current 481 can be generated from the power source 420 to the battery 430 for charging the battery 430. The current 481 can be carried or transmitted from the node 402 to the node 401. However, discharge could be needed to allow another current passing through the node 401 to the node 402 during the charge protection mode.

FIG. 4B is another schematic circuit diagram of a circuitry 4 during the charge protection mode according to some embodiments of the present disclosure.

In some embodiments, during the charge protection mode, the gate electrode of the transistor 411 is pulled down toward the node 401 and becomes low voltage level. The regulation circuit 40 can be turned off. The gate of the transistor 411 can be electrically connected to the node 401. Accordingly, the regulation circuit 40 can be electrically equivalent to the diode 41.

As shown in FIG. 4B, the anode 41a of the diode 41 can be electrically connected to the node 401. The cathode 41b of the diode 41 can be electrically connected to the node 402. In some embodiments, the current 482 can be created or carried from the battery 430 to the power source 420 for discharging. In some embodiments, the current 482 can be transmitted from the node 401 to the node 402 through the transistors 414 and 415.

In some embodiments, the regulation circuit 40 of the circuitry 4 include multiple III-V compound semiconductor layers, and have a higher electron mobility than that using silicon semiconductor layer. Therefore, compared to the regulation circuit of silicon, the area the regulation circuit 40 can be reduced. In addition, the turned-on resistance can also be decreased. As a result, the performance and reliability of the circuit 40 for protecting the battery 430 can be enhanced and improved.

FIG. 4C are schematics illustrating the voltages on different nodes during the charge protection mode according to some embodiments of the present disclosure. In some embodiments shown in FIG. 4C, the voltage VA corresponds to the voltage at the control terminal 451. The voltage VB corresponds to the voltage at the control terminal 452. The voltage VC corresponds to the voltage at the gate electrode of the transistor 411. The current 1A corresponds to the current 481 for charging.

As shown in FIG. 4C, during the duration of 1 ms to 2 ms, the voltage VA is at a low voltage level, the voltage VB is at a low voltage level. The circuitry 4 can be operated in a normal mode for charging the battery 430. The voltage VC is at a high voltage level. The current 1A of charging could be about 27A.

Afterwards, during the duration of 2 ms to 3 ms, the voltage VA is at a high voltage level, the voltage VB is at a low voltage level. The circuitry 4 can be operated in a charge protection mode. The voltage VC is at a low voltage level. The charging is stopped or shutdown. The current 1A of charging could be substantially zero. The discharging is allowed or enabled.

In some embodiments, during the duration of 2 ms to 3 ms, the voltage VA is at a low voltage level, the voltage VB is at a low voltage level. The circuitry 4 can be operated in a normal mode for charging the battery 430. The voltage VC is at a high voltage level. The current 1A of charging could be about 27A.

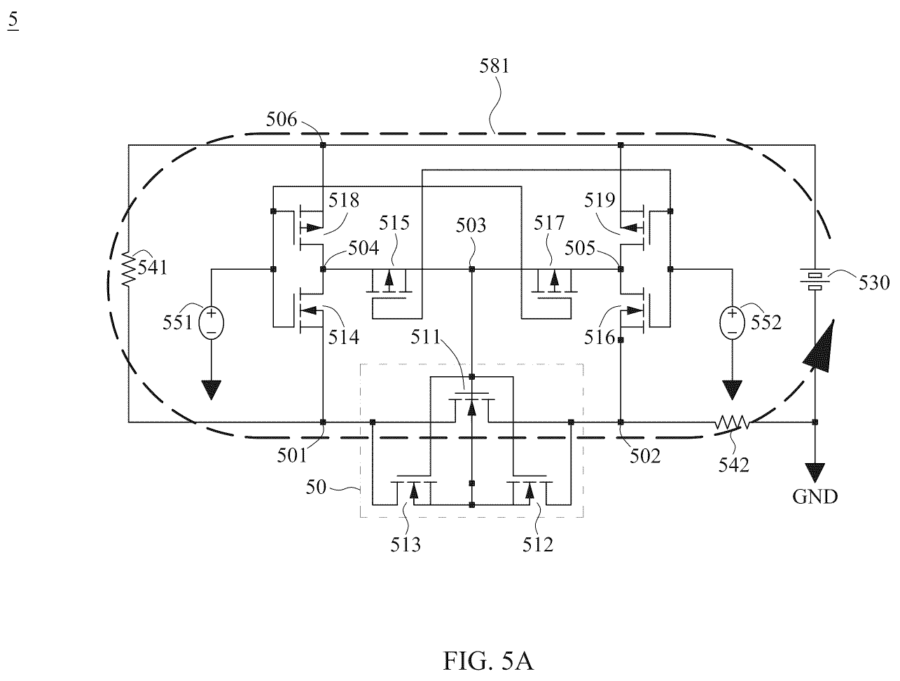

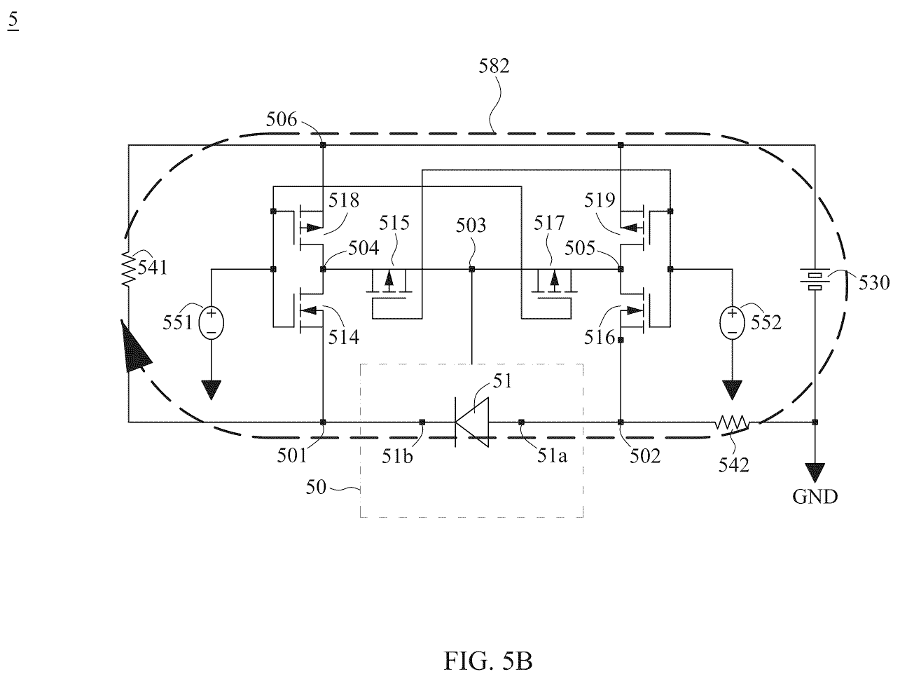

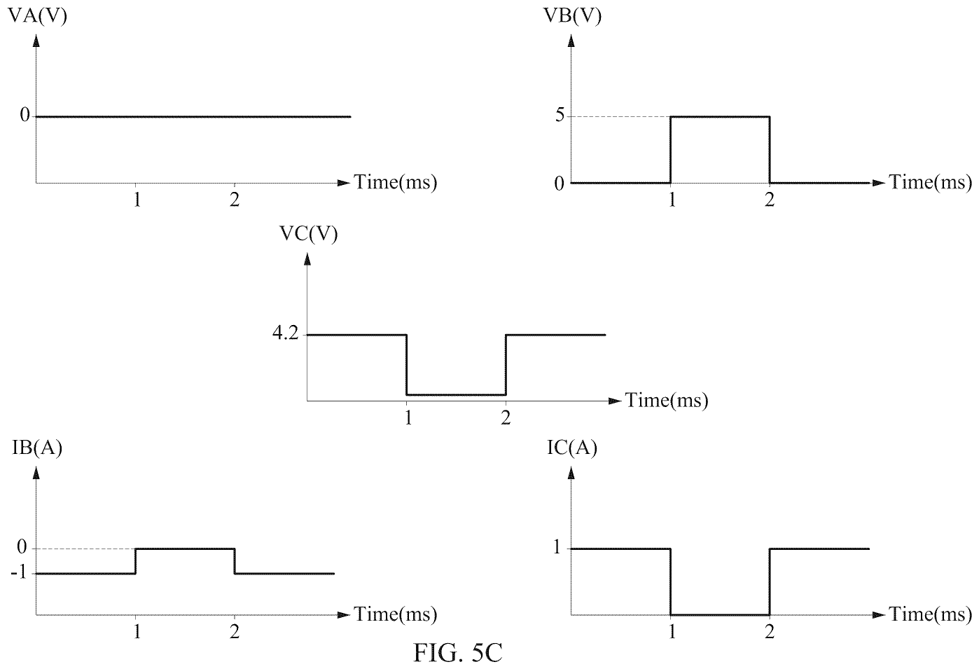

FIG. 5A is a schematic circuit diagram of a circuitry 5 during the discharge protection mode according to some embodiments of the present disclosure. In some embodiments, the circuitry 5 can correspond to the circuitry 3 of FIG. 3A.

In some embodiments, during the discharge protection mode, the control terminal 551 is at low voltage level and the control terminal 552 is at high voltage level. The transistors 515, 515 and 519 are turned off. The transistors 516, 517 and 518 are turned on. The gate electrode of the transistor 511 is pulled down toward the node 502 and becomes low voltage level. Therefore, the regulation circuit 50 can be turned off.

As shown in FIG. 5A, the current 581 can be generated from the battery 530 to the power source 520 for discharging the battery 530. The current 581 can be carried or transmitted from the node 501 to the node 502. However, charging could be needed to allow another current passing through the node 502 to the node 501 during the discharge protection mode.

FIG. 5B is another schematic circuit diagram of a circuitry 5 during the discharge protection mode according to some embodiments of the present disclosure.

In some embodiments, during the charge protection mode, the gate electrode of the transistor 511 is pulled down and becomes low voltage level. The regulation circuit 50 can be turned off. The gate of the transistor 511 can be electrically connected to the node 502. Accordingly, the regulation circuit 50 can be electrically equivalent to the diode 51.

As shown in FIG. 5B, the anode 51a of the diode 51 can be electrically connected to the node 502. The cathode 51b of the diode 51 can be electrically connected to the node 501. In some embodiments, the current 582 can be created or carried from the power source 520 to the battery 530 for charging. In some embodiments, the current 582 can be transmitted from the node 502 to the node 501 through the transistors 516 and 517.

In some embodiments, the regulation circuit 50 of the circuitry 5 include multiple III-V compound semiconductor layers, and have a higher electron mobility than that using silicon semiconductor layer. Therefore, compared to the regulation circuit of silicon, the area the regulation circuit 50 can be reduced. In addition, the turned-on resistance can also be decreased. As a result, the performance and reliability of the circuit 50 for protecting the battery 530 can be enhanced and improved.

FIG. 5C are schematics illustrating the voltages on different nodes during the discharge protection mode according to some embodiments of the present disclosure. In some embodiments shown in FIG. 5C, the voltage VA corresponds to the voltage at the control terminal 551. The voltage VB corresponds to the voltage at the control terminal 552. The voltage VC corresponds to the voltage at the gate electrode of the transistor 511. The current 1B corresponds to the current 581 for discharging. The current 1C corresponds to the current on the resistor 541.

As shown in FIG. 5C, during the duration of 1 ms to 2 ms, the voltage VA is at a low voltage level, the voltage VB is at a low voltage level. The circuitry 5 can be operated in a normal mode for discharging the battery 530. The voltage VC is at a high voltage level. The current 1B of discharging could be about 1A, which can be represented as −1A in terms of charging. The current 1C is around 1A.

Afterwards, during the duration of 2 ms to 3 ms, the voltage VA is at a low voltage level, the voltage VB is at a high voltage level. The circuitry 5 can be operated in a discharge protection mode. The voltage VC is at a low voltage level. The discharging is stopped or shutdown. The current 1B of discharging could be substantially zero. The current 1C is substantially zero. The charging is allowed or enabled.

In some embodiments, during the duration of 2 ms to 3 ms, the voltage VA is at a low voltage level, the voltage VB is at a low voltage level. The circuitry 5 can be operated in a normal mode for discharging the battery 530. The voltage VC is at a high voltage level. The current 1B of discharging could be about 1A, which can be represented as −1A in terms of charging. The current 1C is around 1A.

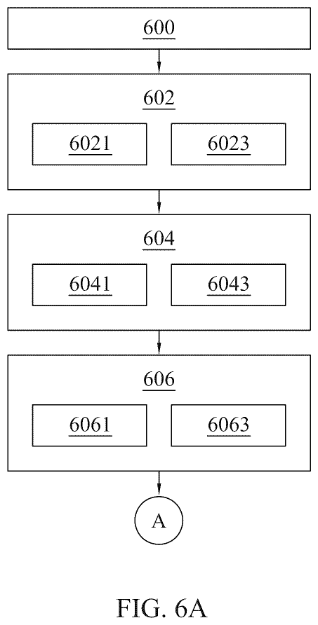

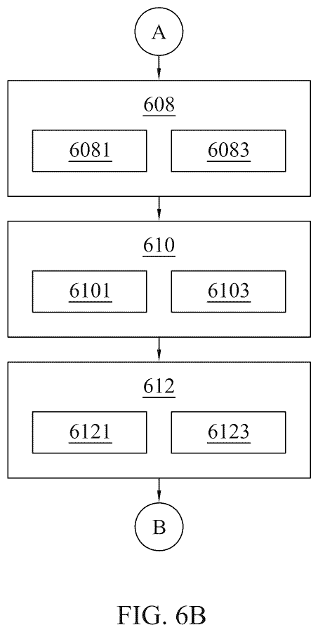

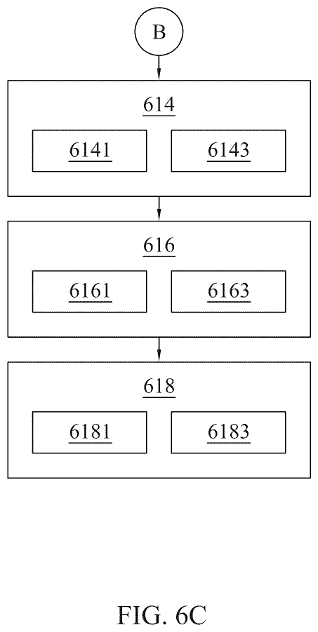

FIG. 6A to FIG. 6C are a flowchart of operations in the manufacture of a circuitry according to some embodiments of the present disclosure. In operation 600, a regulation circuit is formed. The regulation circuit includes a first node, a second node and a third node. The first node electrically connects to a power source, and the second node electrically connects to a cathode of the battery.

The operation 602 can include two operations 6021 and 6023. In operation 6021, a first transistor is formed. In operation 6023, a drain electrode and a source electrode of the first transistor are connected to the first node and the second node.

The operation 604 can include two operations 6041 and 6043. In operation 6041, a second transistor is formed. In operation 6043, a gate electrode of the second transistor is connected to a gate electrode of the first transistor, and a source electrode of the second transistor is connected to the second node.

The operation 606 can include two operations 6061 and 6063. In operation 6061, a third transistor is formed. In operation 6063, a gate electrode of the third transistor is connected to the gate electrode of the first transistor, a source electrode of the third transistor is connected to the first node, and a drain electrode of the third transistor is connected to a drain electrode of the second transistor.

The operation 608 can include two operations 6081 and 6083. In operation 6081, a fourth transistor is formed. In operation 6083, a gate electrode of the fourth transistor is connected to a first control terminal, a source electrode of the fourth transistor is connected to the first node, and a drain electrode of the fourth transistor is connected to a fourth node.

The operation 610 can include two operations 6101 and 6103. In operation 6101, a fifth transistor is formed. In operation 6103, a gate electrode of the fifth transistor is connected to a second control terminal, a source electrode of the fifth transistor is connected to the third node, and a drain electrode of the fifth transistor is connected to the fourth node.

The operation 612 can include two operations 6121 and 6123. In operation 6121, a sixth transistor is formed. In operation 6123, a gate electrode of the sixth transistor is connected to the second control terminal, a source electrode of the sixth transistor is connected to the second node, and a drain electrode of the sixth transistor is connected to a fifth node.

The operation 614 can include two operations 6141 and 6143. In operation 6141, a seventh transistor is formed. In operation 6143, a gate electrode of the seventh transistor is connected to the first control terminal, a source electrode of the seventh transistor is connected to the fifth node, and a drain electrode of the seventh transistor is connected to the third node.

The operation 616 can include two operations 6161 and 6163. In operation 6161, an eighth transistor is formed. In operation 6163, a gate electrode of the eighth transistor is connected to the first control terminal, a source electrode of the eighth transistor is connected to the fourth node, and a drain electrode of the eighth transistor is connected to a sixth node.

The operation 618 can include two operations 6181 and 6183. In operation 6181, a ninth transistor is formed. In operation 6183, a gate electrode of the ninth transistor is connected to the second control terminal, a source electrode of the ninth transistor is connected to the fifth node, and a drain electrode of the ninth transistor is connected to the sixth node.

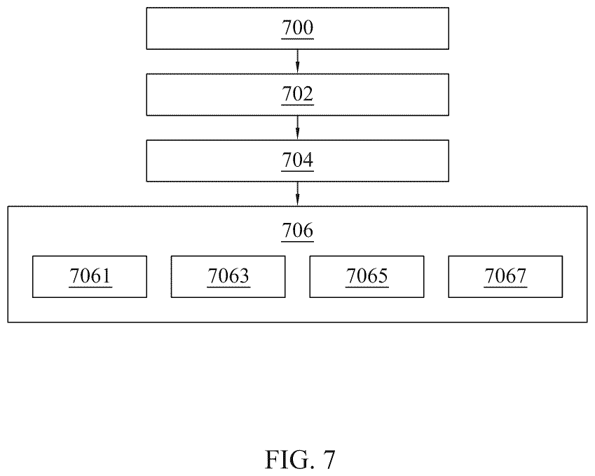

FIG. 7 is a flowchart of operations in the manufacture of a circuitry according to some embodiments of the present disclosure. In operation 700, a regulation circuit includes a first node, a second node and a third node. The first node electrically connects to a power source, and the second node electrically connects to a cathode of the battery.

In operation 702, a first transistor set is formed for electrically connecting to the first node and the third node of the regulation circuit. In operation 704, a second transistor set is formed for electrically connecting to the second node and the third node of the regulation circuit.

The operation 706 can include four operations 7061, 7063, 7065 and 7067. In operation 7061, during a charge protection mode, the regulation circuit is turned off for providing a discharging path from the first node to the second node by electrically connecting the third node to the first node through the first set of transistors. In operation 7063, during a discharge protection mode, the regulation circuit is turned off for providing a charging path from the second node to the first node by electrically connecting the third node to the second node through the second set of transistors.

In operation 7065, during a normal operation mode, the regulation circuit is turned on for passing through the discharging path from the first node to the second node or passing through the charging path from the second node to the first node. In operation 7067, during a standby mode, the regulation circuit is turned off without providing the charging path or the discharging path.

As used herein, spatially relative terms, such as “beneath,” “below,” “lower,” “above,” “upper,” “higher,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conduction with an event or circumstance, the terms can refer to instances in which the event of circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

Several embodiments of the disclosure and features of details are briefly described above. The embodiments described in the disclosure may be easily used as a basis for designing or modifying other processes and structures for realizing the same or similar objectives and/or obtaining the same or similar advantages introduced in the embodiments of the disclosure. Such equivalent constructions do not depart from the spirit and scope of the disclosure, and various variations, replacements, and modifications can be made without departing from the spirit and scope of the disclosure.

To the claims:

1. A circuitry electrically connected to a battery, comprising:
a regulation circuit, comprising a first node, a second node and a third node, wherein the first node electrically connects to a power source, and the second node electrically connects to a cathode of the battery;
a first transistor set, electrically connecting to the first node and the third node of the regulation circuit; and
a second transistor set, electrically connecting to the second node and the third node of the regulation circuit;
wherein when the circuitry is operated in a first mode, the first node electrically connects to the third node through the first transistor set to create a first path from the first node to the second node; and
when the circuitry is operated in a second mode, the second node electrically connects to the third node through the second transistor set to create a second path from the second node to the first node.

2. The circuitry according to claim 1, wherein the regulation circuit comprises:
a first transistor, including a drain electrode connected to the first node and a source electrode connected to the second node;
a second transistor, including a gate electrode connected to a gate electrode of the first transistor and a source electrode connected to the second node; and
a third transistor, including a gate electrode connected to the gate electrode of the first transistor, a source electrode connected to the first node, and a drain electrode connected to a drain electrode of the second transistor.

3. The circuitry according to claim 2, wherein the first transistor comprises:
a substrate;
a first nitride semiconductor layer on the substrate;
a second nitride semiconductor layer on the first nitride semiconductor layer, wherein a band gap of the second nitride semiconductor layer is greater than that of the first nitride semiconductor layer.

4. The circuitry according to claim 3, wherein the gate electrode, the drain electrode and the source electrode of the first transistor are on the second nitride semiconductor layer, and a first distance between the gate electrode and the drain electrode equals to a second distance between the gate electrode and the source electrode.

5. The circuitry according to claim 2, wherein the first transistor set comprises:
a fourth transistor, wherein a gate electrode of the fourth transistor connects to a first control terminal, a source electrode of the fourth transistor connects to the first node, and a drain electrode of the fourth transistor connects to a fourth node; and
a fifth transistor, wherein a gate electrode of the fifth transistor connects to a second control terminal, a source electrode of the fifth transistor connects to the third node, and a drain electrode of the fifth transistor connects to the fourth node.

6. The circuitry according to claim 5, wherein the second transistor set comprises:
a sixth transistor, wherein a gate electrode of the sixth transistor connects to the second control terminal, a source electrode of the sixth transistor connects to the second node, and a drain electrode of the sixth transistor connects to a fifth node; and
a seventh transistor, wherein a gate electrode of the seventh transistor connects to the first control terminal, a source electrode of the seventh transistor connects to the fifth node, and a drain electrode of the seventh transistor connects to the third node.

7. The circuitry according to claim 6, further comprising:
an eighth transistor, wherein a gate electrode of the eighth transistor connects to the first control terminal, a source electrode of the eighth transistor connects to the fourth node, a drain electrode of the eighth transistor connects to a sixth node, and the sixth node connects to an anode of the battery; and
a ninth transistor, wherein a gate electrode of the ninth transistor connects to the second control terminal, a source electrode of the ninth transistor connects to the fifth node, and a drain electrode of the ninth transistor connects to the sixth node.

8. The circuitry according to claim 7, wherein:
the fourth transistor, and the sixth transistor are NMOS transistors, and
the fifth transistor, the seventh transistor, the eighth transistor and the ninth transistor are PMOS transistors.

9. The circuitry according to claim 8, wherein:
the circuitry is operated in the first mode when the first control terminal is at a first logic level and the second control terminal is at a second logic level; and
the circuitry is operated in the second mode when the first control terminal is at the second logic level and the second control terminal is at the first logic level.

10. The circuitry according to claim 9, wherein the circuitry is operated in a third mode when the first control terminal is at the second logic level and the second control terminal is at the second logic level.

11. The circuitry according to claim 10, wherein the circuitry is operated in the third mode, the regulation circuit is enabled for passing through the first path from the first node to the second node and passing through the second path from the second node to the first node.

12. The circuitry according to claim 9, wherein the first logic level corresponds to a high voltage level, and the second logic level corresponds to a low voltage level.

13. The circuitry according to claim 9, wherein the circuitry is operated on a fourth mode when the first control terminal is at the first logic level and the second control terminal is at the first logic level.

14. The circuitry according to claim 13, further comprising:
an AND gate; and
a tenth transistor, wherein a gate electrode of the tenth transistor connects to an output of the AND gate, a drain electrode of the tenth transistor connects to the third node, a source electrode of the tenth transistor connects to a ground, and an input of the AND gate connects to the first control terminal and the second control terminal.

15. The circuitry according to claim 14, wherein the tenth transistor is configured to shut down the regulation circuit during the fourth mode.

16. A method for operating a circuitry, comprising:
providing a regulation circuit comprising a first node, a second node and a third node, wherein the first node electrically connects to a power source, and the second node electrically connects to a cathode of a battery;
providing a first transistor set, electrically connecting to the first node and the third node of the regulation circuit;
providing a second transistor set, electrically connecting to the second node and the third node of the regulation circuit;
when the circuitry is operated in a first mode, turning off the regulation circuit and providing a first path from the first node to the second node by electrically connecting the third node to the first node through the first transistor set; and
when the circuitry is operated in a second mode, turning off the regulation circuit and providing a second path from the second node to the first node by electrically connecting the third node to the second node through the second transistor set.

17. The method according to claim 16, further comprising:
when the circuitry is operated in a third mode, turning on the regulation circuit for passing through the first path from the first node to the second node and passing through the second path from the second node to the first node.

18. The method according to claim 17, further comprising:
when the circuitry is operated in a fourth mode, turning off the regulation circuit to disable the second path or the first path.

19. The method according to claim 16, further comprising:
providing a first transistor;
connecting a drain electrode and a source electrode of the first transistor to the first node and the second node;
providing a second transistor;
connecting a gate electrode of the second transistor to a gate electrode of the first transistor, and connecting a source electrode of the second transistor to the second node;
providing a third transistor; and
connecting a gate electrode of the third transistor to the gate electrode of the first transistor, connecting a source electrode of the third transistor to the first node, and connecting a drain electrode of the third transistor to a drain electrode of the second transistor.

20. The method according to claim 19, further comprising:
providing a fourth transistor;
connecting a gate electrode of the fourth transistor to a first control terminal, connecting a source electrode of the fourth transistor to the first node, and connecting a drain electrode of the fourth transistor to a fourth node;
providing a fifth transistor; and
connecting a gate electrode of the fifth transistor to a second control terminal, connecting a source electrode of the fifth transistor to the third node, and connecting a drain electrode of the fifth transistor to the fourth node.

21. A regulation circuit, comprising:
a first transistor, wherein a drain electrode of the first transistor connects to a first node coupling to a power source, and a source electrode of the first transistor connects to a second node coupling to a battery;
a second transistor, wherein a gate electrode of the second transistor connects to a gate electrode of the first transistor, and a source electrode of the second transistor connects to the second node; and
a third transistor, wherein a gate electrode of the third transistor connects to the gate electrode of the first transistor, and a source electrode of the third transistor connects to the first node;
wherein the regulation circuit is configured to allow carrying a first path during a first mode and carrying a second path during a second mode.

22. The regulation circuit according to claim 21, wherein during the first mode, the regulation circuit is turned off and enables carrying the first path from the battery to the power source.

23. The regulation circuit according to claim 21, wherein during the second mode, the regulation circuit is turned off and enables carrying the second path from the power source to the battery.

24. The regulation circuit according to claim 21, wherein the first transistor comprises:
a substrate;
a first nitride semiconductor layer on the substrate; and
a second nitride semiconductor layer on the first nitride semiconductor layer, wherein a band gap of the second nitride semiconductor layer is greater than that of the first nitride semiconductor layer.

25. The regulation circuit according to claim 24, wherein a drain electrode of the second transistor connects to a drain electrode of the third transistor, and the second transistor and the third transistor are NMOS transistors.
